(19) United States
(12) Patent Application Publication
(10) Pub. No.: US 2014/0320326 A1
(43) Pub. Date: Oct. 30, 2014

(54) Method and Delta-Sigma Converter for a Sensor Signal, More Particularly a Signal of a Rotation Rate Sensor

(71) Applicant: Robert Bosch GmbH, Stuttgart (DE)

(72) Inventor: Alexander Buhmann, Reutlingen (DE)

(21) Appl. No.: 14/357,069

(22) PCT Filed: Oct. 5, 2012
(86) PCT No.: PCT/EP2012/069678

§ 371 Date: May 8, 2014

(30) Foreign Application Priority Data
Nov. 9, 2011 (DE) 10 2011 086 003.7

(51) Int. Cl. H03M 3/00

(52) U.S. Cl. CPC H03M 3/322
USPC 341/143

(57) ABSTRACT

A delta-sigma converter for a sensor signal is configured to emit a digital output signal using the sensor signal. The delta-sigma converter includes a control unit configured to generate a control signal on the basis of a frequency of signal level changes of the digital output signal. The delta-sigma converter further includes a digital compensation unit configured to emit a compensation signal using the digital output signal and the control signal. The delta-sigma converter is further configured to determine the digital output signal also using the compensation signal.

### BACKGROUND INFORMATION

The present invention relates to a delta-sigma converter for a sensor signal, in particular a signal of a rotation rate sensor, to a corresponding method, and to a corresponding computer program product.

Current modern evaluation circuits for rotation rate sensors are based on the principle of a delta-sigma converter using force compensation. In particular, the use of single-bit quantizers is preferable due to the ease of circuit implementation.

Publication DE 10 2005 003 630 A1 discloses a delta-sigma modulator. This publication is directed to a delta-sigma modulator having an oscillatory system having a natural frequency, having an electronic system, and having a control loop that acts on the electronic system from the oscillatory system, and again on the oscillatory system from the electronic system.

The dissertation “Readout Techniques for High-Q Micromachined Vibratory Rate Gyroscopes” by Chinwuba David Ezekwe, University of California at Berkeley, describes techniques for reading out delta-sigma modulators.

### SUMMARY OF THE INVENTION

Against this background, the present invention provides a delta-sigma converter having an adjustment of a loop gain, a method that uses this delta-sigma converter, and a corresponding computer program product, as recited in the main claims. Advantageous embodiments result from the respective subclaims and the following description.

The approach according to the present invention may be provided in a delta-sigma converter using force compensation. A major disadvantage of the evaluation circuits for sigma-delta converters according to the related art is the indeterminate loop gain due not only to the electric filter and the sensor element, but due as well to the variation in the quantizer gain. This results in the signal transfer function and the noise transfer function not corresponding to the optimized transfer function from the system design. Therefore, one of the transfer functions must be determined from the spectral density and corrected to the desired transfer function by feeding in noise. However, the related art uses a visual method that is very time-consuming and requires a great deal of computing effort to automate, image recognition method.

One aspect of the present invention is to determine the loop gain, consisting of the sensor gain, filter gain, converter gain, and quantizer gain, in a hardware-efficient manner, thus enabling simple adjustment at the band end and during operation.

The present invention is based on the knowledge that the activity of the quantizer has a direct correlation to the existing loop gain. The activity A of the quantizer may be determined according to the relationship A=nₜ/nₚ, the variable nₜ denoting the number of actual signal level changes, i.e., state changes, and the variable nₚ denoting the number of theoretically possible signal level changes or state changes in the time interval under consideration. The activity of the quantizer may be determined in a very simple manner using a counter that counts the number of state changes, thus also allowing this approach to be implemented in an area-efficient manner in an ASIC.

The approach described here is now advantageous in that the required adjustment of the loop gain may be determined via a simple measurement of the activity and may thus be adjusted manually or via an integrated controller to a defined value. It is thus possible to achieve an improvement of the digital output signal, in particular the signal-noise ratio of the digital output signal.

The present invention provides a delta-sigma converter for a sensor signal, in particular a signal of a rotation rate sensor,

wherein the delta-sigma converter is designed to output a digital output signal using the sensor signal,

wherein the delta-sigma converter has a control unit that is designed to generate a control signal based on a frequency of signal level changes of the digital output signal,

and wherein the delta-sigma converter has a digital compensation unit that is designed to output a compensation signal using the digital output signal and the control signal,

wherein the delta-sigma converter is furthermore designed to output the digital output signal further using the compensation signal.

A delta-sigma converter may presently be understood to be an electric device that processes sensor signals and outputs control and/or data signals as a function of them. The delta-sigma converter may have an interface, which may have a hardware-based and/or software-based design. In a hardware-based design, the interfaces may, for example, be part of a so-called system ASIC that contains a wide variety of functions. However, it is also possible that the interfaces are self-contained integrated circuits or are made up at least partially of discrete components. In a software-based design, the interfaces may be software modules that, for example, are present on a microcontroller, in addition to other software modules.

A rotation rate sensor may be understood to be a sensor that measures the rotation speed of an object. The angle by which an object has rotated within a period of time may be derived from the rotation speed using integration. The measuring principle may be based on the evaluation of the Coriolis force acting on a mechanically moved system. A delta-sigma converter may be understood to be an analog-digital converter that is derived from the principle of delta modulation. The principle may be based on a rough measurement of the signal using a quantizer. The resulting measurement error may be integrated and compensated incrementally via negative feedback. The quantizer may be a one-bit quantizer. The frequency of signal level changes of the digital output signal may be referred to as activity. A compensation unit may be understood to be a unit that, for example, processes a calibration signal and/or the digital output signal and/or a dither signal whose variance is adjustable, and outputs a compensation signal. The signal-noise ratio of a signal, here, of the digital output signal, may be optimized using the compensation signal.

A dither signal may generally be understood to be dither noise. The dither noise corresponds to white noise, except that it is statistically distributed differently. Various dither signal types are differentiated based on the probability density function of their amplitude distributions.

According to one specific embodiment, the control unit of the delta-sigma converter may be designed to determine the frequency of the signal level change of the digital output signal using a counter. It is thus also possible to determine the frequency of the signal change of the digital output signal in a cost-effective manner using a counter implemented in an ASIC.

It is also advantageous if the delta-sigma converter integrates a force-compensated sensor for providing the sensor signal. A force-compensated sensor may be an analog force-compensated sensor having a micromechanically manufactured measuring element. A unit made up of a delta-sigma converter and a force-compensated sensor may be formed as an MEM unit, i.e., a microelectromechanical unit, and/or an analog unit, thereby making it possible to provide a force-compensated delta-sigma converted signal in a particularly advantageous manner.

In one specific embodiment of the present invention, the control unit may also be designed in such a way as to determine the control signal using a characteristic curve as well. A characteristic curve may generally be understood to be a representation of two interdependent physical variables. Such a specific embodiment of the present invention provides the advantage of a very simple option for programming a predetermined relationship between different variables into a control unit in such a way that a rapid provision of the control signal also without having to make a great numerical or circuit engineering effort.

Furthermore, the characteristic curve may map a frequency of signal level changes of the digital output signal as a function of a loop gain of the delta-sigma converter. The delta-sigma converter may include sensors, filters, converters and/or quantizers. A loop gain may be understood to be a gain that is made up of a sensor gain, a filter gain, a converter gain, and/or a quantizer gain. It is thus possible to implement a rapidly settling control system in a highly advantageous manner.

It is also advantageous if the delta-sigma converter is designed to output the digital output signal using a one-bit quantizer. Such a specific embodiment of the present invention likewise provides the advantage of implementing a control loop that settles as rapidly as possible.

In one specific embodiment of the present invention, the control unit may be designed to determine the control signal in such a way that it corresponds to a changeable variance in dither noise. It is thus possible to achieve settling of the delta-sigma converter that is as rapid as possible in a highly advantageous manner. Dither noise may be understood to be a noise signal that approximately corresponds to white noise, except it is statistically distributed differently. Various dither types are differentiated based on the probability density function of their amplitude distributions.

According to one specific embodiment of the present invention, the control unit of the delta-sigma converter may be designed to determine the control signal using a sliding average of the frequency of signal level changes of the digital output signal. Such a specific embodiment of the present invention also provides the advantage of an implementation of a robust and rapidly settling control loop.

Furthermore, the present invention also comprises a method for generating a digital output signal using a sensor signal, which comprises the following steps:
reading in a sensor signal;
delta-sigma conversion of the sensor signal into a digital output signal;
providing a control signal using a frequency of signal level changes of the digital output signal;
ascertaining a compensation signal using the digital output signal and the control signal; and
changing the digital output signal using the compensation signal.

In addition, the present invention provides a computer program having program code that may be stored on a machine-readable medium such as a semiconductor memory, a hard-disk memory, or an optical memory, for carrying out and/or controlling the steps of the aforementioned method if the computer program is executed on a delta-sigma converter, a control unit, a device, or a data processing system.

The present invention is explained in greater detail below by way of example based on the included drawings.

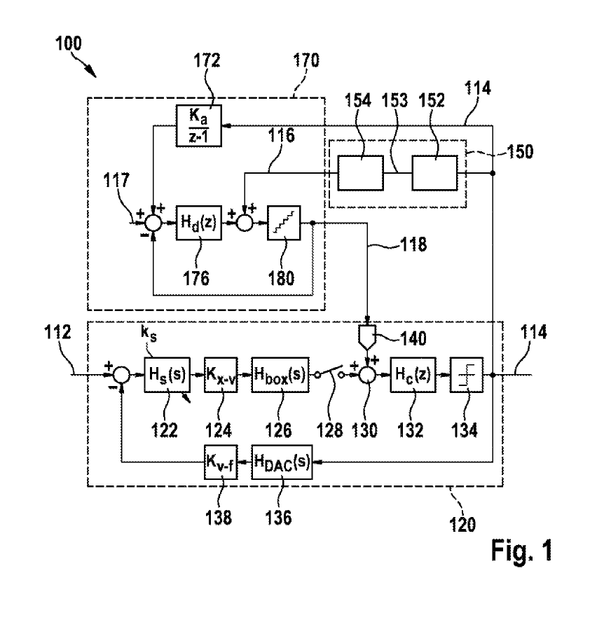

FIG. 1 shows a block diagram of an exemplary embodiment of the present invention as a delta-sigma converter;

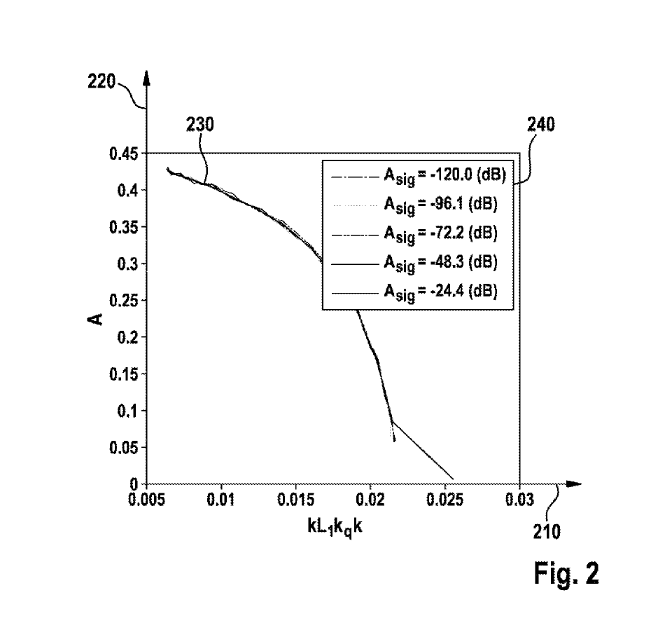

FIG. 2 shows a characteristic curve of an exemplary embodiment of the present invention; and

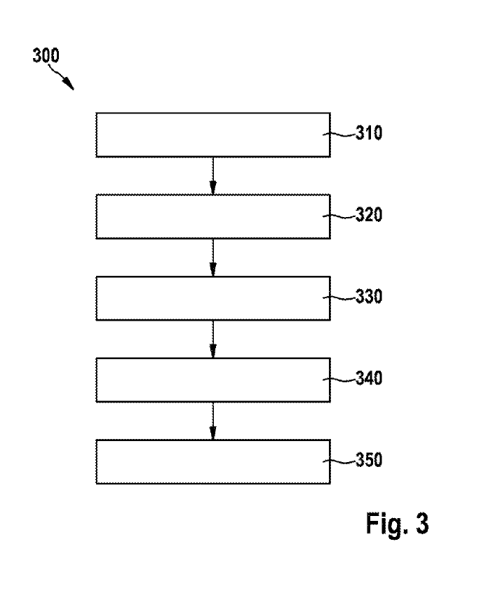

FIG. 3 shows a flow chart of an exemplary embodiment of the present invention as a method.

In the following description of preferred exemplary embodiments of the present invention, identical or similar reference numerals are used for the elements depicted in the various figures and acting similarly; therefore, a description of these elements will not be repeated.

FIG. 1 shows a block diagram of an exemplary embodiment of the present invention as a delta-sigma converter 100. The delta-sigma converter 100 reads in a value of a sensor signal 112, the value representing a Coriolis force of a rotation rate sensor, and outputs a digital output signal 114. The delta-sigma converter 100 is made up of three logical areas: a delta-sigma modulator 120, a control unit 150, and a digital compensation unit 170. The delta-sigma modulator 120 reads in the sensor signal 112 and a compensation signal 118 and outputs the digital output signal 114. The control unit 150 reads in the digital output signal and outputs a control signal 116. The digital compensation unit 170 reads in the digital output signal 114 and the control signal 116 and outputs the compensation signal 118, the compensation signal 118 being routed to the sigma-delta modulator.

The control unit 150 is made up of two modules. An activity counter 152 determines the frequency of signal level changes 153 from the digital output signal 114 at its input and provides it at its output. In an exemplary embodiment not depicted here, the frequency of signal level changes 153 represents a sliding average of the frequency of signal level changes 153 and then provides this sliding average at the output of the activity counter 152 for further processing. An activity controller 154 reads in the frequency of signal level changes 153 at its input and provides the control signal 116 at its output.

The digital compensation unit reads in the digital output signal 114 at its input and routes it through an accumulator 172. The resulting signal after the accumulator 172 is additively connected to a calibration signal 117, the compensation signal 118 still being subtracted from it. The resulting signal is routed to a loop filter 176. The output of the loop filter 176 is additively connected to the control signal 116 and routed to a multi-bit truncator 180. The compensation signal 118 is present at the output of the multi-bit truncator 180.

The delta-sigma modulator 120 receives the sensor signal 112 and the compensation signal 118 and outputs the digital output signal 114 at its output. A force feedback signal 142 is subtracted from the sensor signal 112. The difference is routed through a chain of modules, each having an input and an output. The difference between the sensor signal 112 and the force feedback signal 142 is connected to a measuring element 122. The output of the measuring element 122 is connected to an input of a position-to-voltage converter 124, and an output of the converter 124 is connected to an input of a boxcar filter 126, and an output of the boxcar filter 126 is connected to an input of a sampler 128. The compensation signal 118 is additively connected via a digital-analog converter 140 to a signal at the output of the sampler 128, and the sum is passed to a compensator 132. An output of the condenser 132 is connected to an input of a one-bit quantizer 134. The digital output signal 114 at an output of the one-bit quantizer 134 is routed to the digital compensation unit 170, to the control unit 150, an output of the delta-sigma converter 100, and to a feedback within the delta-sigma modulator 120. The digital output signal 114 in the feedback within the delta-sigma modulator 120 is connected to an input of a feedback digital-analog converter 136. An output of the feedback digital-analog converter 136 is connected to an input of a voltage-to-force converter 138. The force feedback signal 142, which is subtracted from the sensor signal 112 as described above, is present at an output of the voltage-to-force converter 138.

The block diagram in FIG. 1 of an exemplary embodiment of the present invention depicts a schematic structure of an MEM delta-sigma converter 100 having a white dither signal whose variance is adjustable via the control signal 116.

FIG. 1 thus shows a schematic structure of an MEM delta-sigma converter having a dither feed-in, FIG. 1 being based on an illustration from the dissertation by Chinwuba Ezekwe, “Readout Techniques for High-Q Micromachined Vibratory Rate Gyroscopes”, and being augmented by the specific elements of the approach according to the present invention, in particular by the control unit 150, which determines the activity and thus controls the dither 116.

The structure is made up of the MEM delta-sigma converter 100 and the unit for determining the activity 150. In the event that a value from 2^{N} is used as the number of possible state changes, the activity may be determined in a very simple manner using a counter that counts the number of state changes. The following example is provided for clarification: The quantizer 134 has the following output data stream [−1 1 1 1 −1 −1 1 1 1], a value -1 describing a jump from a high level value to a low level value, and a value 1 describing a jump from a low level value to a high level value. The number of possible state changes is 8. The number of state changes is 3. An activity of 0.375 thus results. Together with the information from the following illustration, which is described in greater detail in FIG. 2, the loop gain ∥kqL1(z)∥ may be deduced, which corresponds to 0.0125 in the above example. For example, an optimal value at ∥k_{q}L₁(z)∥=0.01 may be determined from the system design of the MEM delta-sigma modulator 120. Thus, in this case, the dither signal 116 would have to be adjusted in such a way that the activity corresponds to 0.40. This adjustment may be achieved manually or via a PI controller, as shown in FIG. 1. Not shown in FIG. 1 is an additional advantageous specific embodiment having a use of an active control system, which maintains the activity, i.e., the frequency of the signal level changes 153, at a constant value. This is possible at the band end and in ongoing operation.

FIG. 2 shows a simulation of the activity of the quantizer 220 for various loop gains, dither values, and residual signals. As is apparent, an existing rotation rate/quadrature signal would not result in an erroneous estimation. This mapping function should be recalculated for each converter. In FIG. 2, a coordinate system depicts the frequency of signal level changes 220 identified as an activity on the ordinate as a function of a loop gain of the sigma-delta converter (or delta-sigma converter) 210 on the abscissa. Characteristic curves 230 for five different delta-sigma modulators 120 are plotted. A key 240 shows the five different characteristic curves plotted.

FIG. 3 shows a flow chart of an exemplary embodiment of the present invention as a method 300 for generating a digital output signal using a sensor signal. The method 300 comprises a step of reading in 310 a sensor signal and a step of delta-sigma conversion 320 of the sensor signal into a digital output signal. Furthermore, the method 300 comprises a step of providing 330 a control signal using a frequency of signal level changes of the digital output signal, and a step of ascertaining 340 a compensation signal using the digital output signal and the control signal. Finally, the method 300 comprises a step of changing 350 the digital output signal using the compensation signal.

The exemplary embodiments described and shown in the figures are selected only by way of example. Different exemplary embodiments may be combined completely or with respect to individual features. An exemplary embodiment may also be supplemented by features of an additional exemplary embodiment.

Method steps according to the present invention may furthermore be repeated and executed in a sequence other than the one described.

If an exemplary embodiment includes an “and/or” link between a first feature and a second feature, this is to be read as meaning that the exemplary embodiment according to one specific embodiment has both the first feature and the second feature and has either only the first feature or only the second feature according to an additional specific embodiment.

1. A delta-sigma converter for a sensor signal configured to generate a digital output signal using the sensor signal, the delta-sigma converter comprising:
a control unit configured to generate a control signal based on a frequency of signal level changes of the digital output signal; and
a digital compensation unit configured to output a compensation signal using the digital output signal and the control signal, the compensation signal based on a dither signal having a changeable variance,
wherein the control signal corresponds to the changeable variance of the dither signal, and
wherein the delta-sigma converter is configured to generate the digital output signal further using the compensation signal.

2. The delta-sigma converter as claimed in claim 1, further comprising:
a force-compensated sensor configured to provide the sensor signal.

3. The delta-sigma converter as claimed in claim 1, wherein the control unit is configured to determine the control signal using a characteristic curve.

4. The delta-sigma converter as claimed in claim 3, wherein the characteristic curve represents a frequency of signal level changes of the digital output signal as a function of a loop gain of the delta-sigma converter.

5. The delta-sigma converter as claimed in claim 1, wherein the delta-sigma converter is configured to output the digital output signal using a one-bit quantizer.

6. (canceled)

7. The delta-sigma converter as claimed in claim 1, wherein the control unit is configured to determine the control signal using a sliding average of the frequency of signal level changes of the digital output signal.

8. A method for generating a digital output signal using a sensor signal, comprising:
reading in a sensor signal;
converting the sensor signal into a digital output signal using delta-sigma conversion;
generating a control signal using a frequency of signal level changes of the digital output signal;
ascertaining a compensation signal using the digital output signal and the control signal, the compensation signal based on a dither signal having a changeable variance, and the control signal corresponding to the changeable variance of the dither signal; and
changing the digital output signal using the compensation signal.

9. A computer program product comprising:
program code configured to execute a method for generating a digital output signal using a sensor signal, if the program code is executed on a delta-sigma converter or a device, the method including (i) reading in the sensor signal, (ii) converting the sensor signal into the digital output signal using delta-sigma conversion, (iii) generating a control signal using a frequency of signal level changes of the digital output signal, (iv) ascertaining a compensation signal using the digital output signal and the control signal, and (v) changing the digital output signal using the compensation signal,
wherein the compensation signal is based on a dither signal having a changeable variance, and
wherein the control signal corresponds to the changeable variance of the dither signal.
